(19) United States
(12) Patent Application Publication
(10) Pub. No.: US 2011/0140708 A1
(43) Pub. Date: Jun. 16, 2011

(54) SYSTEM, METHOD, AND APPARATUS FOR PROVIDING REDUNDANT POWER CONTROL USING A DIGITAL OUTPUT MODULE

(76) Inventor: William Henry Lueckenbach, Charlottesville, VA (US)

(21) Appl. No.: 12/636,056

(22) Filed: Dec. 11, 2009

(51) Int. Cl. G01R 31/08; H03B 1/00

(52) U.S. Cl. 324/522; 327/108

(57) ABSTRACT

A method for providing redundant power control to a load using a digital output module includes coupling at least one sourcing driver to a voltage supply and to a first output terminal, coupling at least one sinking driver to a voltage return and to a second output terminal, and coupling a load to the first output terminal and to the second output terminal. The method also includes sensing a failure in one of the at least one sourcing driver and the at least one sinking driver.

### BACKGROUND

The embodiments described herein relate generally to a digital output module and, more particularly, to providing a redundant power supply to a load using an I-pattern circuit within a single digital output module.

At least some known output modules are only capable of sinking to a load or sourcing current from the load, but not both. Such known output modules include input circuitry that receives a predefined input signal, and other circuitry that generates a source signal or a sink signal based on the input signal. Moreover, such known output modules include output stage circuitry that sources power to the load from a power source, or sinks power from the load to the power source via a return path. However, such known output modules do not provide both sourcing drivers and sinking drivers within a single module.

Moreover, at least some known control systems include both sourcing output modules and sinking output modules that are connected to form an I-pattern for use in providing redundant means to remove power from a load. However, such known control systems require independent control and programming of both modules to control the load. This adds development and commissioning cost to the control system.

Furthermore, at least some known output modules are capable of pulse testing to prove a capability of state changes of the load. However, control systems must be programmed to operate the independent sourcing output driver module and the independent sinking output module in tandem for each load configured in such an I-pattern. This also adds development and commissioning cost to the control system, and impacts controller performance.

### BRIEF DESCRIPTION

In one aspect, a method is provided for supplying redundant power control to a load using a digital output module. The method includes coupling at least one sourcing driver to a voltage supply and to a first output terminal, coupling at least one sinking driver to a voltage return and to a second output terminal, and coupling a load to the first output terminal and to the second output terminal. The method also includes sensing a failure in one of the at least one sourcing driver and the at least one sinking driver.

In another aspect, a digital output module is provided. The digital output module includes a first output terminal and a second output terminal each configured to couple to a load. The digital output module also includes at least one sourcing driver coupled to the first output terminal and to a voltage supply, and at least one sinking driver coupled to the second output terminal and to a voltage return, wherein the at least one sourcing driver and the at least one sinking driver are configured to provide redundant power control to the load in an energized-to-run configuration.

In another aspect, a system is provided, including a voltage source having a voltage supply and a voltage return, at least one load, and a first digital output module. The digital output module includes a terminal block having a voltage supply terminal, a voltage return terminal, a first output terminal, and a second output terminal, wherein the voltage supply terminal is coupled to the voltage supply, the voltage return terminal is coupled to the voltage return, and the first output terminal and the second output terminal are coupled to the at least one load. The digital output module also includes at least one sourcing driver coupled to the voltage supply terminal and to the first output terminal, and at least one sinking driver coupled to the voltage return terminal and to the second output terminal, wherein the first digital output module is configured to selectively provide redundant power control to the at least one load via the first output terminal and the second output terminal.

### BRIEF DESCRIPTION OF THE DRAWINGS

The embodiments described herein may be better understood by referring to the following description in conjunction with the accompanying drawings.

FIG. 1 is a schematic diagram of an exemplary digital output module that is embodied as a single module.

FIG. 2 is a schematic diagram of an exemplary I-pattern circuit that is provided within the digital output module shown in FIG. 1.

FIG. 3 is a schematic diagram of an exemplary H-pattern circuit that is formed using two I-pattern circuits shown in FIG. 2.

FIG. 4 is a flowchart that illustrates an exemplary method for providing redundant power to a load using the I-pattern circuit shown in FIG. 2.

### DETAILED DESCRIPTION

Exemplary embodiments of systems, methods, and apparatus for use in providing redundant power to a load using a single digital output module are described herein. The embodiments described herein facilitate using a single sinking driver and a single sourcing driver to produce an I-pattern circuit within a single digital output module that provides power control redundancy in energized-to-run configurations. Moreover, the embodiments described herein facilitate using two I-pattern circuits to produce an H-pattern circuit that provides power control power redundancy and availability in energized-to-run configurations and in energized-to-shutdown configurations. Furthermore, the embodiments described herein enable pulse testing an I-pattern circuit without requiring a processor or network interface unit.

Exemplary technical effects of the systems, methods, and apparatus described herein include at least one of: (a) orienting a plurality of sourcing drivers and a plurality of sinking drivers within a single digital output module, such that a sourcing driver and an associated sinking driver form an I-pattern circuit for use in providing redundant power to a load; (b) sensing a failure in either the sourcing driver or the sinking driver of the I-pattern circuit during operation; (c) indicating the failure of the driver to the controller; (d) performing a pulse test on either the sourcing driver or the sinking driver without interaction with an external processor; and (e) sensing the current passing through the driver and de-energizing the driver in an over load condition or a short circuit condition.

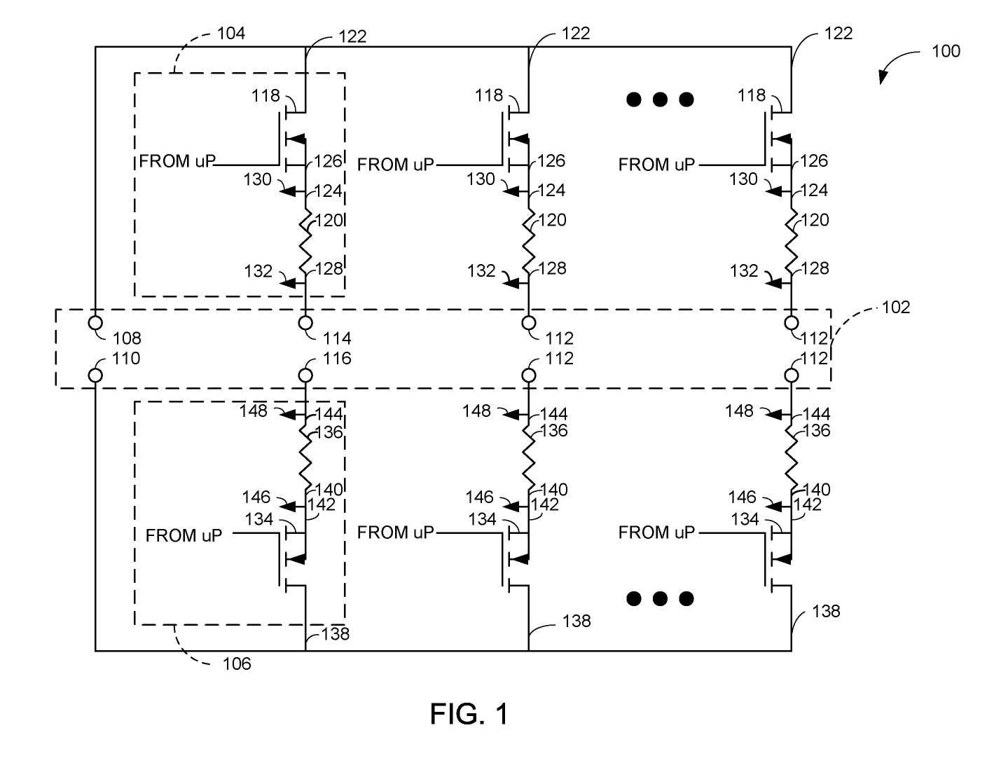

FIG. 1 is a schematic diagram of an exemplary digital output module 100 that is embodied as a single module. In the exemplary embodiment, digital output module 100 includes a terminal block 102, a plurality of sourcing drivers 104, and a plurality of sinking drivers 106. In the exemplary embodiment, a number of sourcing drivers 104 is equal to a number of sinking drivers 106.

Terminal block 102 includes a voltage supply terminal 108 and a voltage return terminal 110 that are each configured to couple to a voltage source (not shown in FIG. 1). More specifically, voltage supply terminal 108 is configured to couple to a voltage supply (not shown in FIG. 1), and voltage return terminal 110 is configured to couple to a voltage return (not shown in FIG. 1). Moreover, in the exemplary embodiment, terminal block 102 includes a plurality of output terminals 112 that are each configured to couple to a load (not shown in FIG. 1). For example, terminal block 102 includes a first output terminal 114 and a second output terminal 116.

In the exemplary embodiment, each sourcing driver 104 is coupled to voltage supply terminal 108 and to an associated first output terminal 114. Moreover, each sourcing driver 104 includes a switching device 118 and a sensing resistor 120. Switching device 118 is configured to couple to an external processor (not shown). In the exemplary embodiment, switching device 118 is a transistor. Alternatively, switching device 118 may be embodied as an electro-mechanical relay, a solid state relay, a relay driver, or a smart switch. In the exemplary embodiment, switching device 118 is coupled at a first end 122 to voltage supply terminal 108. Sensing resistor 120 is coupled at a first end 124 to a second end 126 of switching device 118. Moreover, sensing resistor 120 is coupled at a second end 128 to first output terminal 114 at a second end 128. Furthermore, each sourcing driver 104 includes a first diagnostics terminal 130 and a second diagnostics terminal 132. First diagnostics terminal 130 is coupled to sensing resistor first end 124, and second diagnostics terminal 132 is coupled to sensing resistor second end 128. First diagnostics terminal 130 and second diagnostics terminal 132 enable measurement of current through sensing resistor 120 to facilitate diagnosing short circuit protection, no load detection, over current, failure of switching device 118, and/or pulse testing.

In the exemplary embodiment, each sinking driver 106 is coupled to voltage return terminal 110 and to an associated second output terminal 116. Moreover, each sinking driver 106 includes elements similar to sourcing driver 104. Specifically, each sinking driver 106 includes a switching device 134 and a sensing resistor 136. Switching device 134 is configured to couple to an external processor (not shown in FIG. 1). In the exemplary embodiment, switching device 134 is coupled at a first end 138 to voltage return terminal 110. Sensing resistor 136 is coupled at a first end 140 to a second end 142 of switching device 134. Moreover, sensing resistor 136 is coupled at a second end 144 to second output terminal 116. Furthermore, each sinking driver 106 includes a first diagnostics terminal 146 and a second diagnostics terminal 148. First diagnostics terminal 146 is coupled to sensing resistor first end 140, and second diagnostics terminal 148 is coupled to sensing resistor second end 144. First diagnostics terminal 146 and second diagnostics terminal 148 enable measurement of current through sensing resistor 136 to facilitate diagnosing short circuit protection, no load detection, over current, failure of switching device 134, and/or pulse testing.

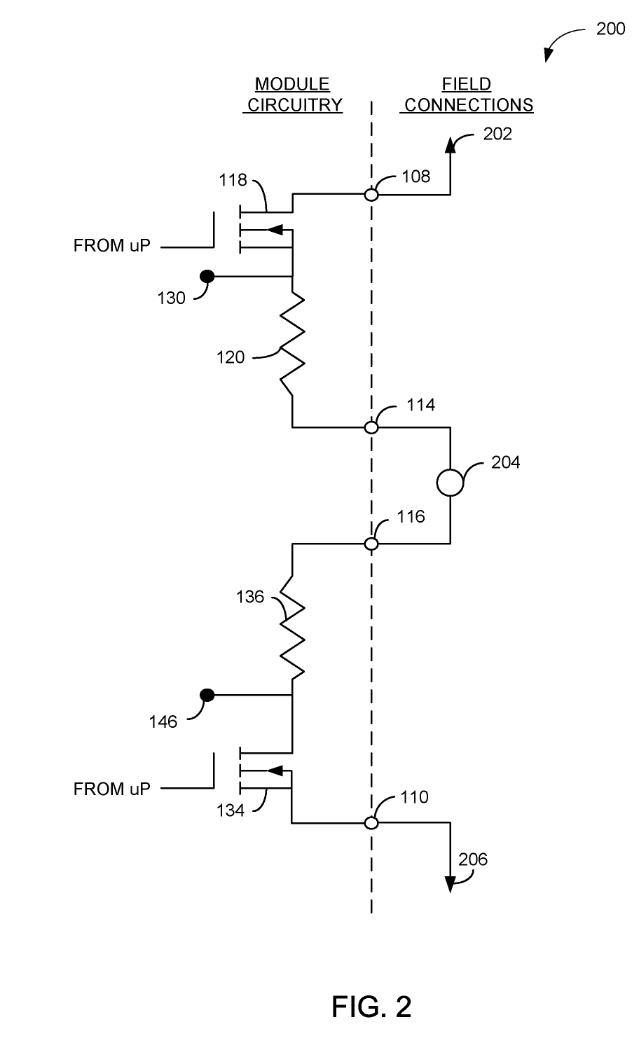

FIG. 2 is a schematic diagram of an exemplary I-pattern circuit 200 that is provided within a single digital output module, such as digital output module 100 (shown in FIG. 1). I-pattern circuit 200 provides power control redundancy in energized-to-run configurations.

More specifically, and in the exemplary embodiment, I-pattern circuit 200 includes sourcing driver 104 and sinking driver 106. As described above, sourcing driver 104 includes a first switching device, such as switching device 118, which is coupled to a voltage supply 202 via voltage supply terminal 108. Sourcing driver 104 also includes a first sensing resistor, such as sensing resistor 120, which is coupled to first switching device 118 and to first output terminal 114. First output terminal 114 is coupled to a load 204.

Moreover, and as described above, sinking driver 106 includes a second switching device, such as switching device 134, which is coupled to a voltage return 206 via voltage return terminal 110. Sinking driver 106 also includes a second sensing resistor, such as sensing resistor 136, which is coupled to second switching device 134 and to second output terminal 116. Second output terminal 116 is coupled to load 204.

During operation, diagnosis of current flowing through first sensing resistor 120 and second sensing resistor 136 is used to sense a failure in sourcing driver 104 or sinking driver 106. For example, if a failure is sensed, such as first switching device 118 failing short or first output terminal 114 being coupled to voltage supply 202, a fault condition is communicated to a controller (not shown in FIG. 2). Similarly, if a failure is sensed, such as second switching device 134 failing short or second output terminal 116 being coupled to voltage return 206, a fault condition is communicated to the controller.

Moreover, I-pattern circuit 200 may be used to pulse test sourcing driver 104 and/or sinking driver 106 without the use of an external processor. For example, to pulse test sourcing driver 104 when load 204 is de-energized, sinking driver 106 is activated, and load 204 is rapidly activated and deactivated by pulsing sourcing driver 104 on and off while current through load 204 is measured via first diagnostics terminals 130 and 146. If current flow is detected through load 204, sourcing driver 104 is operational. Similarly, to pulse test sinking driver 106 when load 204 is de-energized, sourcing driver 104 is activated, and load 204 is rapidly activated and deactivated by pulsing sinking driver 106 on and off while current through load 204 is measured via first diagnostics terminals 130 and 146. If current flow is detected through load 204, sinking driver 106 is operational.

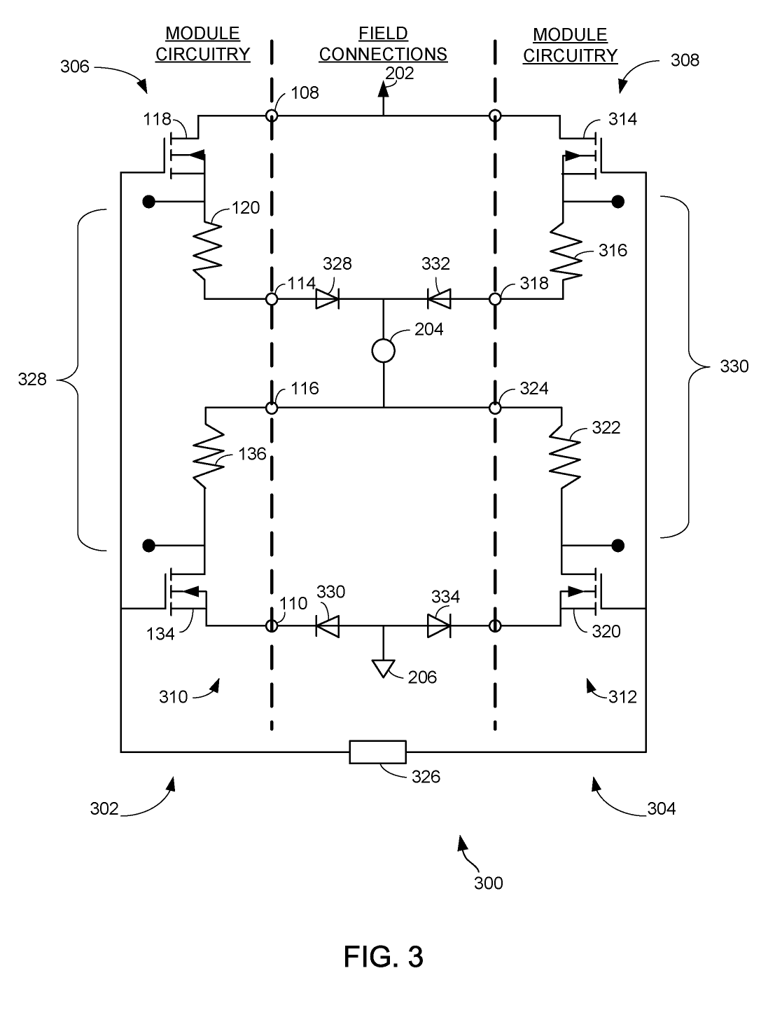

FIG. 3 is a schematic diagram of an exemplary H-pattern circuit 300 that is formed using two digital output modules, such as two digital output modules 100 (shown in FIG. 1). H-pattern circuit 300 provides power redundancy in energized-to-run configurations and in energized-to-shutdown configurations.

As shown in FIG. 3, H-pattern circuit 300 includes two I-pattern circuits 200, such as a first I-pattern circuit 302 and a second I-pattern circuit 304. Accordingly, H-pattern circuit 300 includes a first sourcing driver 306, a second sourcing driver 308, a first sinking driver 310, and a second sinking driver 312. First sourcing driver 306 and first sinking driver 310 each includes substantially the same elements as shown in FIG. 2. Specifically, first sourcing driver 306 includes first switching device 118, first sensing resistor 120, and first output terminal 114. Similarly, first sinking driver 310 includes second switching device 134, second sensing resistor 136, and second output terminal 116. Second sourcing driver 308 includes third switching device 314, third sensing resistor 316, and third output terminal 318. Similarly, second sinking driver 312 includes fourth switching device 320, fourth sensing resistor 322, and fourth output terminal 324. In the exemplary embodiment, H-pattern circuit 300 is coupled to a processor 326. Specifically, each switching device 118, 134, 314, and 320 is coupled to processor 326, and is configured to receive activation and deactivation commands from processor 326. Moreover, H-pattern circuit 300 includes a plurality of blocking diodes 328, 330, 332, and 334. In the exemplary embodiment, blocking diodes 328, 330, 332, and 334 prevent current from first I-pattern circuit 302 from powering up second I-pattern circuit 304 when second I-pattern circuit 304 is de-energized for maintenance or is in any other non-standard mode of operation.

During operation, diagnosis of current flowing through first sensing resistor 120 and third sensing resistor 316 is used to sense a failure in first sourcing driver 306 or second sourcing driver 310, respectively. For example, if a failure is sensed, such as first output terminal 114 being coupled to voltage supply 202, a fault condition is communicated to processor 326. Moreover, if an over load or over current condition is sensed in sourcing driver 306, then sourcing driver 306 is de-energized and a fault condition is communicated to processor 326.

Moreover, H-pattern circuit 300 may be used to pulse test first sourcing driver 306 and first sinking driver 308, or to pulse test second sourcing driver 310 and second sinking driver 312 without the use of an external processor. The pulse testing of each I-pattern circuit 302 and 304 operates independently as described above. For a fast-response load 204, independent operation of the pulse test could inadvertently energize load 204. Specifically, load 204 may be energized if a pulse test of first I-pattern 302 overlaps a pulse test of second I-pattern 304. To prevent unwanted activation of load 204 in H-pattern circuit 300, processor 326 schedules the pulse testing in different modules. In some embodiments, pulse testing different modules is scheduled to occur at different times of the day. For example, first I-pattern circuit 302 may be tested on even hours and second I-pattern circuit 304 may be tested on odd hours.

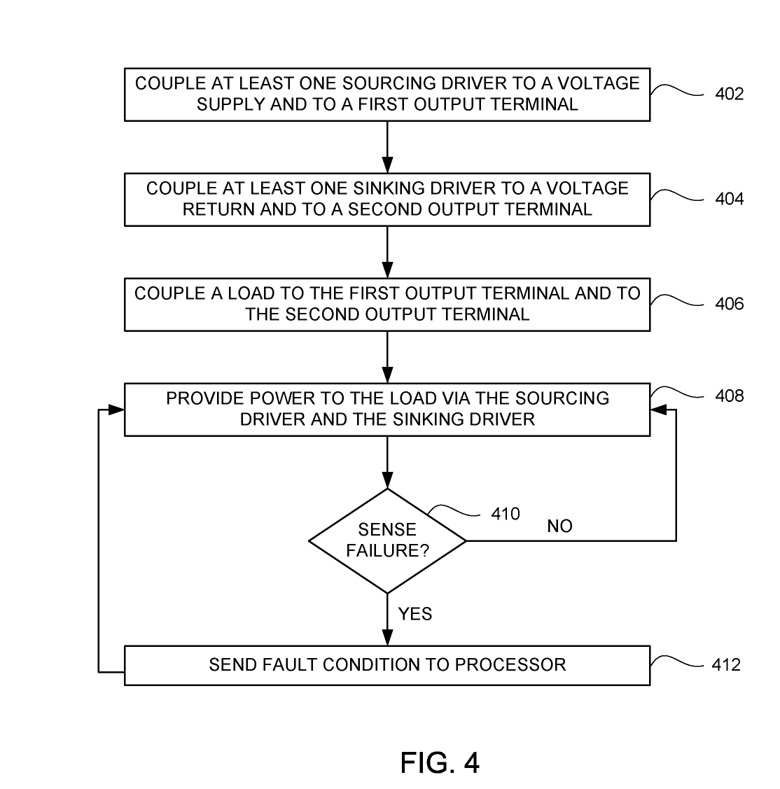

FIG. 4 is a flowchart 400 that illustrates an exemplary method for providing redundant power control to load 204 (shown in FIG. 2) using I-pattern circuit 200 (shown in FIG. 2) provided in a single-module digital output module 100 (shown in FIG. 1).

In the exemplary embodiment, and referring to FIG. 1 and FIG. 2, at least one sourcing driver 104 is coupled 402 to voltage supply 202 and to first output terminal 114. More specifically, first end 122 of first switching device 118 is coupled to voltage supply terminal 108, which is coupled to voltage supply 202. Moreover, first end 124 of first sensing resistor 120 is coupled to second end 126 of first switching device 118. In addition, second end 128 of first sensing resistor 120 is coupled to first output terminal 114. Similarly, at least one sinking driver 106 is coupled 404 to voltage return 206 and to second output terminal 116. More specifically, first end 138 of second switching device 134 is coupled to voltage return terminal 110, which is coupled to voltage return 206. Moreover, first end 140 of second sensing resistor 136 is coupled to second end 142 of second switching device 134. In addition, second end 144 of second sensing resistor 136 is coupled to second output terminal 116.

Moreover, in the exemplary embodiment, load 204 is coupled 406 to first output terminal 114 and to second output terminal 116. I-pattern circuit 200 then provides 408 power to load 204 via sourcing driver 104 and sinking driver 106. During operation, I-pattern circuit 200 senses 410 a failure in either sourcing driver 104 or sinking driver 106 based on measured current through and/or voltage across load 204 via first diagnostics terminals 130 and 146. More specifically, the current through load 204, first sensing resistor 120, and second sensing resistor 136 is measured, and the voltage at second diagnostic terminals 132 and 148 is measured. If no failure is sensed 410, I-pattern circuit 200 continues to operate and/or perform diagnostics. If a failure is sensed 412, a fault message is communicated to processor 326.

Exemplary embodiments of systems, methods, and apparatus for providing redundant power to a load using a single digital output module are described above in detail. The systems, methods, and apparatus are not limited to the specific embodiments described herein but, rather, operations of the methods and/or components of the system and/or apparatus may be utilized independently and separately from other operations and/or components described herein. Furthermore, the described operations and/or components may also be defined in, or used in combination with, other systems, methods, and/or apparatus, and are not limited to practice with only the systems, methods, and storage media as described herein.

The order of execution or performance of the operations in the embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

In some embodiments, the term “processor” refers generally to any programmable system including systems and microcontrollers, reduced instruction set circuits (RISC), application specific integrated circuits (ASIC), programmable logic circuits, and any other circuit or processor capable of executing the functions described herein. The above examples are exemplary only, and thus are not intended to limit in any way the definition and/or meaning of the term processor.

When introducing elements of aspects of the invention or embodiments thereof, the articles “a,” “an,” “the,” and “said” are intended to mean that there are one or more of the elements. The terms “comprising,” including,” and “having” are intended to be inclusive and mean that there may be additional elements other than the listed elements.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for providing redundant power control to a load using a digital output module, said method comprising:
coupling at least one sourcing driver to a voltage supply and to a first output terminal;
coupling at least one sinking driver to a voltage return and to a second output terminal;
coupling a load to the first output terminal and to the second output terminal; and
sensing a failure in one of the at least one sourcing driver and the at least one sinking driver.

2. A method in accordance with claim 1, wherein coupling at least one sourcing driver to a voltage supply and to a first output terminal comprises:
coupling a first end of a first switching device to the voltage supply;
coupling a first end of a first sensing resistor to a second end of the first switching device; and
coupling a second end of the first sensing resistor to the first output terminal.

3. A method in accordance with claim 1, wherein coupling at least one sinking driver to a voltage return and to a second output terminal comprises:
coupling a first end of a second switching device to the voltage return;
coupling a first end of a second sensing resistor to a second end of the second switching device; and
coupling a second end of the second sensing resistor to the second output terminal.

4. A method in accordance with claim 3, wherein sensing a failure in one of the at least one sourcing driver and the at least one sinking driver comprises:
measuring a current through the load and at least one of the first sensing resistor and the second sensing resistor;
sensing the failure in one of the at least one sourcing driver and the at least one sinking driver based on the measured current.

5. A method in accordance with claim 1, further comprising communicating a fault condition to a processor in response to sensing a failure in one of the at least one sourcing driver and the at least one sinking driver.

6. A digital output module comprising:
a first output terminal configured to couple to a load;
a second output terminal configured to couple to the load;
at least one sourcing driver coupled to said first output terminal and to a voltage supply; and
at least one sinking driver coupled to said second output terminal and to a voltage return, said at least one sourcing driver and said at least one sinking driver configured to provide redundant power control to the load in an energized-to-run configuration.

7. A digital output module in accordance with claim 6, wherein said at least one sourcing driver comprises a first switching device configured to generate power to provide to the load, said first switching device coupled to the voltage supply at a first end.

8. A digital output module in accordance with claim 7, wherein said at least one sourcing driver further comprises:
a first sensing resistor having a first end and a second end, the first end of said first sensing resistor coupled to a second end of said first switching device, the second end of said first sensing resistor coupled to said first output terminal;
a first diagnostics terminal coupled to the first end of said first sensing resistor; and
a second diagnostics terminal coupled to the second end of the said first sensing resistor.

9. A digital output module in accordance with claim 7, wherein said at least one sinking driver comprises a second switching device configured to return power from the load, said second switching device coupled to the voltage return at a first end.

10. A digital output module in accordance with claim 9, wherein said at least one sinking driver further comprises:
a second sensing resistor having a first end and a second end, the first end coupled to a second end of said second switching device, the second end of said second sensing resistor coupled to said second output terminal;
a first diagnostics terminal coupled to the first end of said second sensing resistor; and
a second diagnostics terminal coupled to the second end of the said second sensing resistor.

11. A digital output module in accordance with claim 6, wherein said digital output module is configured to:
sense a failure in one of said at least one sourcing driver and said at least one sinking driver; and
communicate a fault condition to a processor in response to sensing the failure.

12. A digital output module in accordance with claim 6, wherein said at least one sourcing driver comprises a plurality of sourcing drivers, and said at least one sinking driver comprises a plurality of sinking drivers, each sourcing driver of said plurality of sourcing drivers paired with a respective sinking driver of said plurality of sinking drivers.

13. A digital output module in accordance with claim 6, wherein said digital output module is configured to perform pulse testing without processor intervention.

14. A system comprising:
a voltage source comprising a voltage supply and a voltage return;
at least one load;
a first digital output module comprising:
a terminal block comprising a voltage supply terminal, a voltage return terminal, a first output terminal, and a second output terminal, said voltage supply terminal coupled to said voltage supply, said voltage return terminal coupled to said voltage return, said first output terminal and said second output terminal coupled to said at least one load;
at least one sourcing driver coupled to said voltage supply terminal and to said first output terminal; and
at least one sinking driver coupled to said voltage return terminal and to said second output terminal, said first digital output module configured to selectively provide redundant power control to said at least one load via said first output terminal and said second output terminal.

15. A system in accordance with claim 14, wherein said at least one sourcing driver comprises:
a first switching device configured to generate power to provide to said at least one load, said first switching device coupled to said voltage supply terminal at a first end;
a first sensing resistor having a first end and a second end, the first end of said first sensing resistor coupled to a second end of said first switching device, the second end of said first sensing resistor coupled to said first output terminal;
a first diagnostics terminal coupled to the first end of said first sensing resistor; and
a second diagnostics terminal coupled to the second end of said first sensing resistor.

16. A system in accordance with claim 15, wherein said at least one sinking driver comprises:
a second switching device configured to return power from said at least one load, said second switching device coupled to said voltage return terminal at a first end;
a second sensing resistor having a first end and a second end, the first end of said second sensing resistor coupled to a second end of said second switching device, the second end of said sensing resistor coupled to said second output terminal;
a first diagnostics terminal coupled to the first end of said second sensing resistor; and
a second diagnostics terminal coupled to the second end of said second sensing resistor.

17. A system in accordance with claim 16, wherein said first switching device and said second switching device each comprises at least one of a transistor, an electro-mechanical relay, a solid state relay, a relay driver, and a smart switch.

18. A system in accordance with claim 14, wherein said first digital output module is configured to:
sense a failure in one of said at least one sourcing driver and said at least one sinking driver; and
communicate a fault condition to a processor in response to sensing the failure.

19. A system in accordance with claim 14, wherein said at least one sourcing driver comprises a plurality of sourcing drivers, and said at least one sinking driver comprises a plurality of sinking drivers, each sourcing driver of said plurality of sourcing drivers paired with a respective sinking driver of said plurality of sinking drivers.

20. A system in accordance with claim 14, further comprising a second digital output module comprising:
a second terminal block comprising a voltage supply terminal, a voltage return terminal, a first output terminal, and a second output terminal, said voltage supply terminal coupled to said voltage supply, said voltage return terminal coupled to said voltage return, said first output terminal and said second output terminal coupled to said at least one load;
at least one sourcing driver coupled to said voltage supply terminal and to said first output terminal; and
at least one sinking driver coupled to said voltage return terminal and to said second output terminal of said second terminal block, said second digital output module configured to selectively provide redundant power control to said at least one load via said first output terminal and said second output terminal of said second terminal block in response to a failure of said first digital output module.
